(19) United States
(12) Patent Application Publication
(10) Pub. No.: US 2026/0246477 A1
(43) Pub. Date: Aug. 20, 2026

(54) Time-interleaved analog-to-digital converter and calibration method therefor

(71) Applicant: REALTEK SEMICONDUCTOR CORPORATION, HSINCHU (TW)

(72) Inventor: SHIH-HSIUNG HUANG, HSINCHU (TW)

(21) Appl. No.: 19/443,334

(22) Filed: Jan. 8, 2026

(30) Foreign Application Priority Data
Feb. 17, 2025 (TW) 114105814

(51) Int. Cl. H03M 1/10

(52) U.S. Cl. CPC H03M 1/1014

(57) ABSTRACT

A time-interleaved analog-to-digital converter (TIADC) includes first and second asynchronous sub-analog-to-digital converters (ADCs). The first and second asynchronous sub-ADCs convert an input signal at different time points to respectively generate a first digital output code and a second digital output code. The first and second asynchronous sub-ADCs respectively generate a first conversion completion signal and a second conversion completion signal upon completion of one analog-to-digital conversion operation. A method for calibrating the TIADC includes the following steps: generating a control signal according to the first conversion completion signal and the second conversion completion signal; and changing the conversion speed of an analog-to-digital conversion operation of at least one of the first asynchronous sub-ADC and the second asynchronous sub-ADC according to the control signal.

### BACKGROUND OF THE INVENTION

### Field of the Invention

The present invention generally relates to an analog-to-digital converter (ADC), and more particularly, to a time-interleaved analog-to-digital converter (TIADC) and a method for calibrating the TIADC.

### Description of Related Art

A TIADC includes multiple sub-ADCs, each of which samples the input signal according to a sampling clock with the same frequency but different phases, and alternately generates its own digital output code as the output of the TIADC. For example, when the TIADC includes four sub-ADCs (e.g., ADC1, ADC2, ADC3, and ADC4), the four sub-ADCs sample the input signal in the following sequence: ADC1 → ADC2 → ADC3 → ADC4 → ADC1 → ADC2 → ….

Due to variations in manufacturing process, voltage, and temperature, the time required for the sub-ADCs to complete one analog-to-digital conversion may be different. Therefore, it is necessary to adjust the operating speed of the sub-ADCs (i.e., to calibrate the TIADC) to improve the performance of the TIADC (e.g., to increase accuracy or reduce power consumption).

### SUMMARY OF THE INVENTION

In view of the issues of the prior art, an object of the present invention is to provide a TIADC and a calibration method therefor, so as to make an improvement to the prior art.

According to one aspect of the present invention, a TIADC is provided. The TIADC is configured to convert an input signal to generate a digital output signal and includes an analog-to-digital converter (ADC) group, a digital code calibration circuit, and a sub-ADC calibration circuit. The ADC group includes a first asynchronous sub-ADC and a second asynchronous sub-ADC. The first asynchronous sub-ADC and the second asynchronous sub-ADC convert the input signal at different time points to respectively generate a first digital output code and a second digital output code. The first asynchronous sub-ADC and the second asynchronous sub-ADC respectively generate a first conversion completion signal and a second conversion completion signal upon completion of one analog-to-digital conversion operation. The digital code calibration circuit is coupled to the ADC group and is configured to correct one of the first digital output code and the second digital output code to obtain the digital output signal. The sub-ADC calibration circuit is coupled to the ADC group and the digital code calibration circuit and is configured to generate a control signal according to the first conversion completion signal and the second conversion completion signal. At least one of the first asynchronous sub-ADC and the second asynchronous sub-ADC changes a conversion speed of an analog-to-digital conversion operation according to the control signal.

According to another aspect of the present invention, a method for calibrating a TIADC is provided. The TIADC includes a first asynchronous sub-ADC and a second asynchronous sub-ADC. The first asynchronous sub-ADC and the second asynchronous sub-ADC convert an input signal at different time points to respectively generate a first digital output code and a second digital output code. The first asynchronous sub-ADC and the second asynchronous sub-ADC respectively generate a first conversion completion signal and a second conversion completion signal upon completion of one analog-to-digital conversion operation. The method includes the following steps: generating a control signal according to the first conversion completion signal and the second conversion completion signal; and changing a conversion speed of an analog-to-digital conversion operation of at least one of the first asynchronous sub-ADC and the second asynchronous sub-ADC according to the control signal.

The technical means embodied in the embodiments of the present invention can solve at least one of the problems of the prior art. Therefore, compared to the prior art, the present invention can improve the performance of the TIADC.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is the functional block diagram of a TIADC according to an embodiment of the present invention.

FIG. 2 is the functional block diagram of a sub-ADC according to an embodiment of the present invention.

FIG. 3 shows the waveforms of the operation timing of the sub-ADCs according to an embodiment of the present invention.

FIG. 4 is the functional block diagram of a sub-ADC calibration circuit according to an embodiment of the present invention.

FIG. 5 is the functional block diagram of a sub-ADC calibration circuit according to another embodiment of the present invention.

FIG. 6 shows a truth table according to an embodiment of the present invention.

FIG. 7 is the flowchart of the method for calibrating a TIADC according to an embodiment of the present invention.

FIG. 8 is the flowchart of step S710 from FIG. 7 according to an embodiment.

FIG. 9 is the flowchart of step S710 from FIG. 7 according to another embodiment.

FIG. 10 illustrates the implementation details of step S720 from FIG. 7 according to an embodiment.

FIG. 11 illustrates the implementation details of step S720 from FIG. 7 according to another embodiment.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes a time-interleaved analog-to-digital converter (TIADC) and a calibration method therefor. On account of that some or all elements of the TIADC could be known, the detail of such elements is omitted provided that such detail has little to do with the features of this disclosure, and that this omission nowhere dissatisfies the specification and enablement requirements. Some or all of the processes of the method for calibrating the TIADC may be implemented by software and/or firmware and can be performed by the TIADC or its equivalent. A person having ordinary skill in the art can choose components or steps equivalent to those described in this specification to carry out the present invention, which means that the scope of this invention is not limited to the embodiments in the specification.

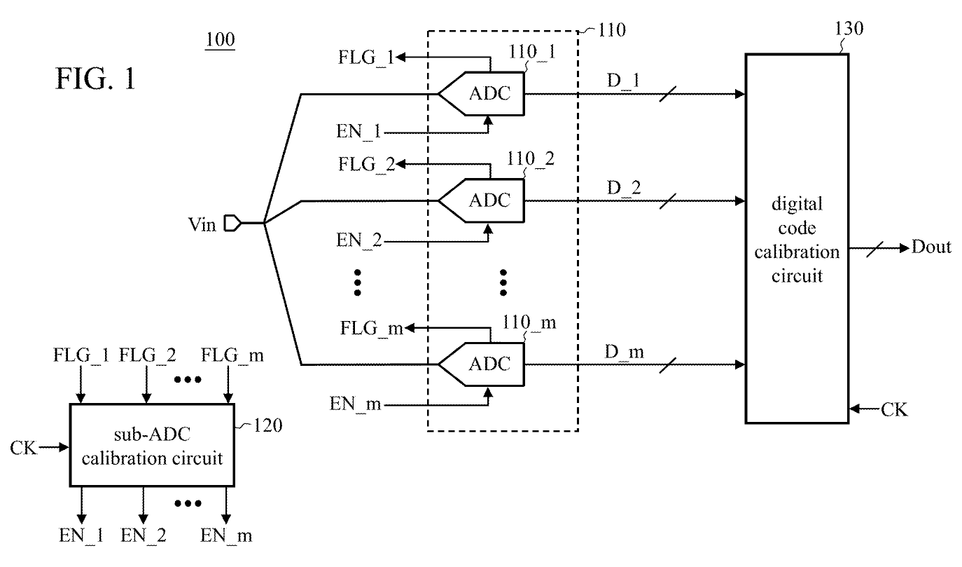

FIG. 1 is the functional block diagram of a TIADC according to an embodiment of the present invention. The TIADC 100 includes the ADC group 110, the sub-ADC calibration circuit 120, and the digital code calibration circuit 130, all of which are coupled to one another. The sub-ADC calibration circuit 120 and the digital code calibration circuit 130 operate according to the system clock CK. The TIADC 100 converts the input signal Vin and generates the digital output signal Dout.

The ADC group 110 is an asynchronous ADC, meaning that the time required for each sub-ADC (110_1, 110_2, …, 110_m) to perform an analog-to-digital conversion operation varies each time. The ADC group 110 includes m sub-ADCs (including the sub-ADC 110_1, the sub-ADC 110_2, …, and the sub-ADC 110_m, where m is an integer greater than or equal to 2). The sub-ADC 110_1 samples the input signal Vin, and generates the digital output code D_1 and the conversion completion signal FLG_1. The sub-ADC 110_2 samples the input signal Vin, and generates the digital output code D_2 and the conversion completion signal FLG_2. The sub-ADC 110_m samples the input signal Vin, and generates the digital output code D_m and the conversion completion signal FLG_m. The conversion completion signal FLG_k indicates that the sub-ADC 110_k has completed one analog-to-digital conversion operation (e.g., the least significant bit (LSB) of the digital output code D_k has been generated) (1 ≦ k ≦ m). More specifically, in some embodiments, when all bits of the digital output code D_k are generated, the sub-ADC 110_k changes the value or level of the conversion completion signal FLG_k (e.g., from a low level to a high level).

The digital code calibration circuit 130 sequentially corrects the digital output code D_1, the digital output code D_2, …, and the digital output code D_m, and outputs the corrected digital output code as the digital output signal Dout.

Since the ADC group 110 is an asynchronous ADC, although the sub-ADC 110_k is given a preset time (e.g., a fixed time) to perform the analog-to-digital conversion operation, the sub-ADC 110_k will have a longer idle time (i.e., not operating) when the sub-ADC 110_k completes the analog-to-digital conversion operation earlier. On the contrary, when the preset time is insufficient, the sub-ADC 110_k cannot complete the analog-to-digital conversion operation within the preset time; that is, the sub-ADC 110_k does not change the value or level of the conversion completion signal FLG_k before the preset time ends.

The sub-ADCs (110_1, 110_2, …, 110_m) operate further according to their respective sub-control signals (the sub-control signal EN_1, the sub-control signal EN_2, …, the sub-control signal EN_m). The sub-control signals are generated by the sub-ADC calibration circuit 120.

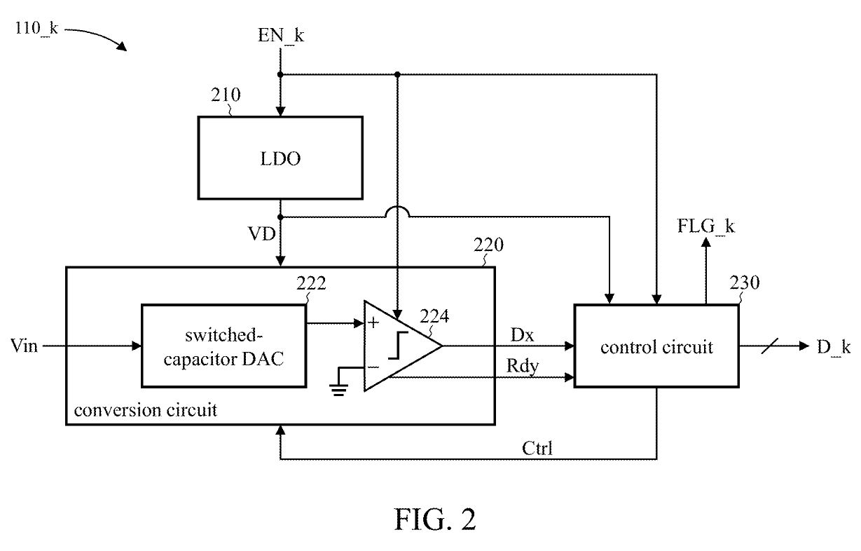

Reference is made to FIG. 2, which is a functional block diagram of a sub-ADC according to an embodiment of the present invention. The sub-ADC 110_k (1 ≦ k ≦ m) includes the low-dropout regulator (LDO) 210, the conversion circuit 220, and the control circuit 230, all of which are coupled to one another.

The LDO 210 provides the operating voltage VD to the conversion circuit 220 and/or the control circuit 230. More specifically, the sources of the operating voltages for the switched-capacitor DAC 222, the comparator 224, and the control circuit 230 (hereinafter referred to as the three target circuits) include but are not limited to the following implementations: (1) the operating voltage of one of the three target circuits is the operating voltage VD, while the operating voltages of the other two are not the operating voltage VD (e.g., they are other supply voltages within the sub-ADC 110_k or the system voltage of the TIADC 100); (2) the operating voltages of two of the three target circuits are the operating voltage VD, and the operating voltage of the other target circuit is not the operating voltage VD; or (3) the operating voltages of the three target circuits are the operating voltage VD.

Controlled by the control signal Ctrl from the control circuit 230, the conversion circuit 220 converts the input signal Vin into a digital intermediate digital code Dx. The control circuit 230 generates the control signal Ctrl based on its built-in counter, and generates the digital output code D_k based on multiple intermediate digital codes Dx. The analog-to-digital conversion operation of the sub-ADC 110_k (or the conversion circuit 220) can refer to the operation in which the sub-ADC 110_k (or the conversion circuit 220) determines all bits of the digital output code D_k.

When the sub-ADC 110_k is an asynchronous SAR ADC, the conversion circuit 220 includes the switched-capacitor DAC 222 and the comparator 224, while the control circuit 230 includes a successive-approximation register and logic circuits (not shown). The operating voltage VD can serve as the power supply voltage of the comparator 224 or the logic circuits. Every time a comparison operation is completed, the comparator 224 changes the value or level of the comparison completion signal Rdy (e.g., from a low level to a high level). The control circuit 230 generates, according to the comparison completion signal Rdy, an asynchronous clock (not shown) required for the sub-ADC 110_k to perform the analog-to-digital conversion operation. The control circuit 230 further uses the control signal Ctrl to control, according to the current intermediate digital code Dx, the multiple switches of the switched-capacitor DAC 222 to be turned on or off to generate the next intermediate digital code Dx. When the control circuit 230 has determined all the bits of the digital output code D_k, the control circuit 230 issues a conversion completion signal FLG_k. The control circuit 230 can delay the asynchronous clock according to the sub-control signal EN_k. Generating the asynchronous clock according to the comparison completion signal Rdy is well known to people having ordinary skill in the art, and therefore, further elaboration is omitted for brevity. It should be noted that the asynchronous SAR ADC is used only as an example, and the sub-ADC 110_k can also be other types of ADCs, for example, an asynchronous pipeline ADC (also known as an asynchronous pipelined ADC).

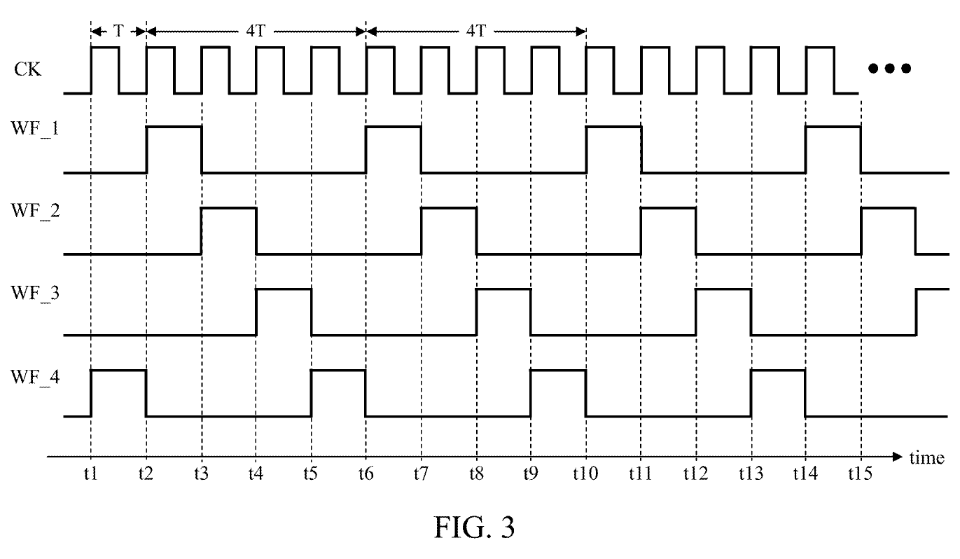

Reference is made to FIG. 3, which shows the waveforms of the operation timing of the sub-ADCs according to an embodiment of the present invention. The system clock CK (with cycle T) is the operating clock of the TIADC 100. In the example of FIG. 3, m equals 4, and the operation waveforms WF_1, WF_2, WF_3, and WF_4 correspond to the sub-ADCs 110_1, 110_2, 110_3, and 110_4, respectively. That is to say, the timing of the sub-ADCs of the ADC group 110 (i.e., the sequence of performing analog-to-digital conversion operations) is as follows: 110_1 → 110_2 → 110_3 → 110_4 → 110_1 → …. The operating cycle of each sub-ADC is 4T.

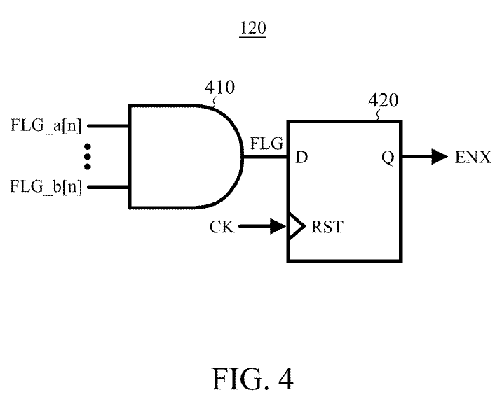

Reference is made to FIG. 4, which is a functional block diagram of the sub-ADC calibration circuit 120 according to an embodiment of the present invention. The sub-ADC calibration circuit 120 includes a logic circuit 410 and a D flip-flop 420 that are coupled to each other. The logic circuit 410 generates the indication signal FLG based on at least the conversion completion signal FLG_a[n] and the conversion completion signal FLG_b[n], wherein the suffix “[n]” represents the n^{th} cycle. For example (referring to FIG. 3), the sub-ADCs 110_1 to 110_4 respectively generate the conversion completion signals FLG_1[n] to FLG_4[n] between the time points t2 to t6 (the n^{th} cycle), and respectively generate the conversion completion signals FLG_1[n+1] to FLG_4[n+1] between the time points t6 to t10 (the (n+1)^{th} cycle). The D flip-flop 420 latches the indication signal FLG, and outputs the indication signal FLG as the control signal ENX according to the system clock CK.

Reference is made to FIGS. 1 to 4. In the embodiment of FIG. 4, the conversion completion signal FLG_a[n] and the conversion completion signal FLG_b[n] may be any two of the conversion completion signals FLG_1 to FLG_m (2 ≦ m), and the sub-control signals EN_1 to EN_m are all equal to the control signal ENX (i.e., the sub-ADCs 110_1 to 110_m are all controlled by the same control signal ENX). The following uses m = 4 as an example for discussion.

In some embodiments, the sub-ADC calibration circuit 120 generates the control signal ENX according to temporally adjacent sub-ADCs. For example, the conversion completion signals FLG_a[n] and FLG_b[n] can be the conversion completion signals FLG_1[n] and FLG_2[n], respectively, or can be the conversion completion signals FLG_4[n] and FLG_1[n], respectively.

In other embodiments, the sub-ADC calibration circuit 120 generates the control signal ENX according to sub-ADCs that are not temporally adjacent; that is, there is a third analog-to-digital conversion operation between the first analog-to-digital conversion operation (corresponding to the conversion completion signal FLG_a[n]) and the second analog-to-digital conversion operation (corresponding to the conversion completion signal FLG_b[n]). For example, the conversion completion signals FLG_a[n] and FLG_b[n] can be the conversion completion signals FLG_1[n] and FLG_3[n], respectively (i.e., the third analog-to-digital conversion operation is performed by the sub-ADC 110_2); alternatively, they can be the conversion completion signals FLG_2[n] and FLG_4[n], respectively (i.e., the third analog-to-digital conversion operation is performed by the sub-ADC 110_3).

In other embodiments, the sub-ADC calibration circuit 120 generates the control signal ENX according to different conversion completion signals in different cycles. For example, the conversion completion signals FLG_a[n] and FLG_b[n] are the conversion completion signals FLG_1[n] and FLG_2[n], respectively, and the conversion completion signals FLG_a[n+1] and FLG_b[n+1] are the conversion completion signals FLG_3[n+1] and FLG_4[n+1], respectively.

In other embodiments, the sub-ADC calibration circuit 120 generates the control signal ENX according to the conversion completion signals of all sub-ADCs in the ADC group 110. For example, the logic circuit 410 generates the indication signal FLG according to the conversion completion signals FLG_1, FLG_2, FLG_3, and FLG_4.

As discussed above, the control signal ENX can represent the overall operating speed of the ADC group 110, and the sub-ADC calibration circuit 120 uses the control signal ENX to adjust all or some of the sub-ADCs. For example, when the conversion completion signals FLG_a[n] and FLG_b[n] both indicate that the analog-to-digital conversion operation of the corresponding sub-ADC is relatively slow (fast), the sub-ADC calibration circuit 120 outputs a low (high)-level control signal ENX to control all or some of the sub-ADCs of the ADC group 110 to accelerate (slow down) the analog-to-digital conversion operation. When the analog-to-digital conversion operation is too slow, accelerating the analog-to-digital conversion operation can improve the accuracy of the TIADC 100. When the analog-to-digital conversion operation is too fast, slowing down the analog-to-digital conversion operation can reduce the overall power consumption of the TIADC 100. Reference is made to FIG. 2, the adjustment includes but is not limited to the following 3 embodiments.
(1) The LDO 210 raises (lowers) the operating voltage VD according to the low (high)-level sub-control signal EN_k (e.g., by generating multiple candidate voltages through a voltage division technique) to increase (decrease) the operating speed of the conversion circuit 220 and the control circuit 230, thereby enhancing (reducing) the overall operating speed of the sub-ADC 110_k.
(2) The comparator 224 raises (lowers) the operating current according to the low (high)-level sub-control signal EN_k (e.g., by providing multiple current sources with different current values) to increase (decrease) its own operating speed, thereby enhancing (reducing) the overall operating speed of the sub-ADC 110_k.
(3) The control circuit 230 lowers (raises) the delay time of the asynchronous clock according to the low (high)-level sub-control signal EN_k (e.g., by providing multiple delay paths with different delay times) to enhance (reduce) the overall operating speed of the sub-ADC 110_k. Note that since the ADC group 110 is an asynchronous ADC, the clock cycle of the asynchronous clock is determined by the delay paths in the control circuit 230.

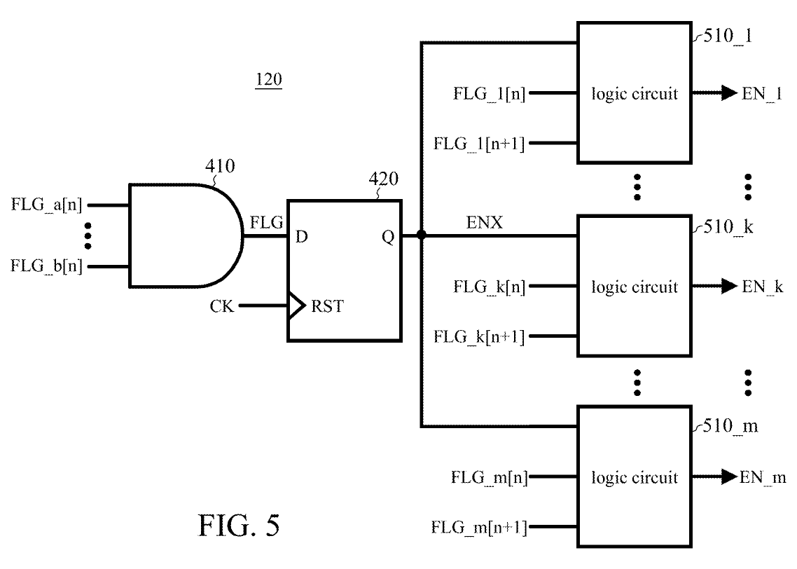

Reference is made to FIG. 5, which is a functional block diagram of the sub-ADC calibration circuit 120 according to another embodiment of the present invention. The sub-ADC calibration circuit 120 includes a logic circuit 410, a D flip-flop 420, and m logic circuits 510_1 to 510_m (which generate sub-control signals EN_1 to EN_m, respectively). The logic circuit 510_k (1 ≦ k ≦ m) generates the sub-control signal EN_k based on the control signal ENX, the conversion completion signal FLG_k[n], and the conversion completion signal FLG_k[n+1].

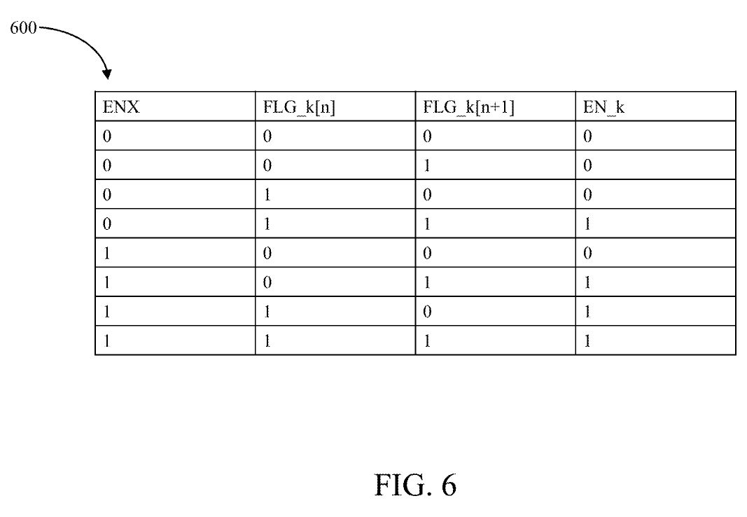

Reference is made to FIG. 6, which shows an embodiment of the truth table 600 according to the present invention. The logic circuits 510_1 to 510_m operate according to the truth table 600. In the example of FIG. 6, when at least two of the control signal ENX, the conversion completion signal FLG_k[n], and the conversion completion signal FLG_k[n+1] are at a low level (logic 0) (e.g., the 1^{st}, 2^{nd}, 3^{rd}, and 5^{th} rows in the truth table 600, representing that the overall operating speed of the ADC group 110 is relatively slow and/or the operating speed of the sub-ADC 110_k in at least one of two consecutive operating cycles is relatively slow), the sub-ADC calibration circuit 120 outputs a low-level sub-control signal EN_k to control the sub-ADC 110_k to perform an analog-to-digital conversion operation at a speed greater than or equal to the speed of the current analog-to-digital conversion operation. The 4^{th}, 6^{th}, 7^{th}, and 8^{th} rows in the truth table 600 represent the opposite meanings, and further elaboration is omitted for brevity.

Compared to the embodiment of FIG. 4, in the embodiment of FIG. 5, the sub-ADC calibration circuit 120 further adjusts the operating speed of the sub-ADC 110_k based on the conversion completion signal FLG_k of the sub-ADC 110_k itself, thereby achieving a more precise adjustment.

In summary, because in any operating cycle (as denoted by “4T” in FIG. 3), the sub-ADC calibration circuit 120 can obtain indication signals FLG from more than two sub-ADCs, the sub-ADC calibration circuit 120 can accumulate the data required for calibration more quickly, thereby converging the calibration of the TIADC 100 faster and achieving the purpose of improving the performance of the TIADC.

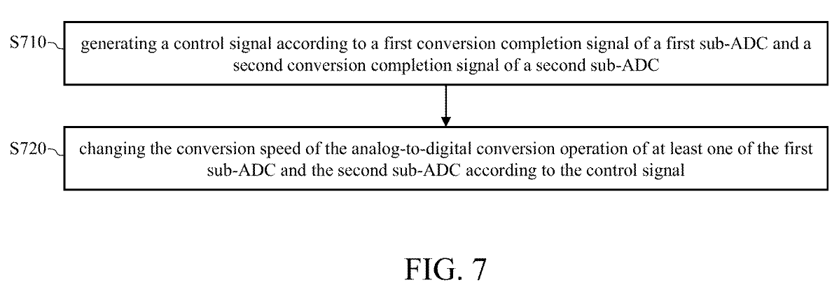

In addition to the aforementioned TIADC 100, the present invention also correspondingly discloses a method for calibrating the TIADC. This method is executed by the aforementioned sub-ADC calibration circuit 120 or its equivalent device. FIG. 7 is a flowchart of the method according to an embodiment. The flow includes the following steps.

Step S710: The sub-ADC calibration circuit 120 generates a control signal according to a first conversion completion signal of the first sub-ADC and a second conversion completion signal of the second sub-ADC. For example, in the embodiment of FIG. 4, the sub-ADC calibration circuit 120 can generate the control signal ENX according to the conversion completion signals FLG_1 and FLG_2. For another example, in the embodiment of FIG. 5, the sub-ADC calibration circuit 120 can generate the sub-control signal EN_k according to the conversion completion signals FLG_1 and FLG_2.

Step S720: The sub-ADC calibration circuit 120 changes the conversion speed of the analog-to-digital conversion operation of at least one of the first sub-ADC (e.g., the sub-ADC 110_1) and the second sub-ADC (e.g., the sub-ADC 110_2) according to the control signal.

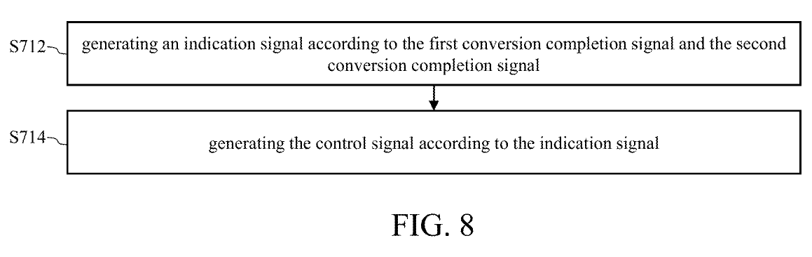

Reference is made to FIG. 8, which is the flowchart of step S710 from FIG. 7 according to an embodiment. The embodiment in FIG. 8 corresponds to FIG. 4 and includes the following steps.

Step S712: The logic circuit 410 generates an indication signal FLG according to the first conversion completion signal (e.g., the conversion completion signal FLG_1) and the second conversion completion signal (e.g., the conversion completion signal FLG_2).

Step S714: The D flip-flop 420 generates the control signal ENX according to the indication signal FLG.

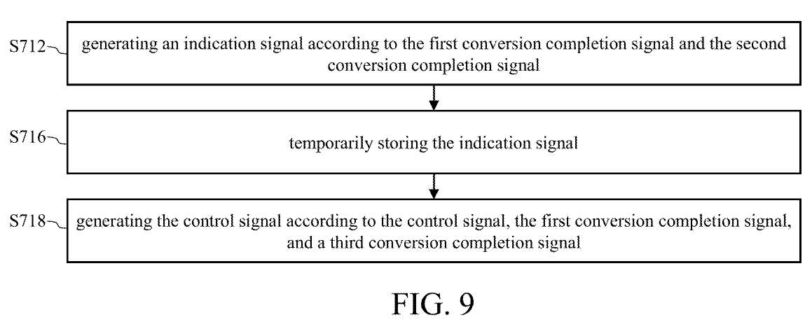

Reference is made to FIG. 9, which is the flowchart of step S710 from FIG. 7 according to another embodiment. The embodiment of FIG. 9 corresponds to FIG. 5. In addition to step S712, the embodiment of FIG. 9 further includes the following steps.

Step S716: The D flip-flop 420 temporarily stores the indication signal FLG.

Step S718: The logic circuit (e.g., the logic circuit 510_1) generates the control signal (e.g., the sub-control signal EN_1) according to the control signal ENX, the first conversion completion signal (e.g., the conversion completion signal FLG_1[n]), and a third conversion completion signal (e.g., the conversion completion signal FLG_1[n+1]).

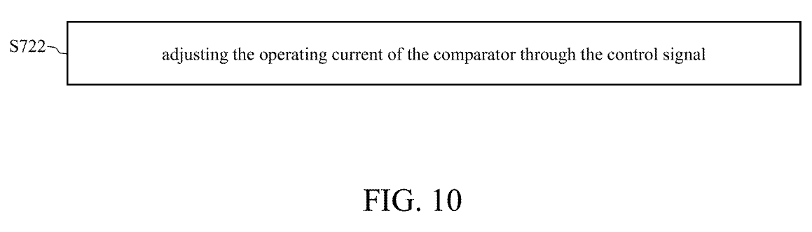

Reference is made to FIG. 10, which illustrates the implementation details of step S720 from FIG. 7 according to an embodiment, including the following steps.

Step S722: The sub-ADC calibration circuit 120 adjusts the operating current of the comparator 224 through the control signal (e.g., the control signal ENX or the sub-control signal EN_k).

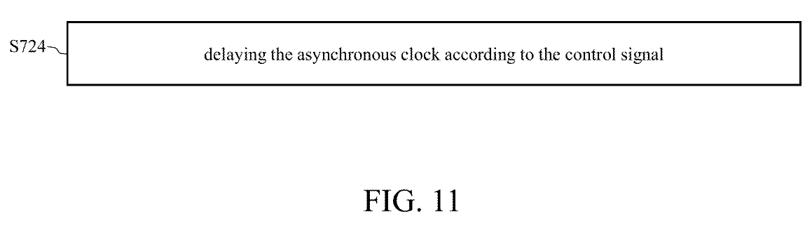

Reference is made to FIG. 11, which illustrates the implementation details of step S720 from FIG. 7 according to another embodiment, including the following steps.

Step S724: The control circuit 230 delays the asynchronous clock according to the control signal (e.g., the control signal ENX or the sub-control signal EN_k). For example, the delay time can be changed by selecting different delay paths.

Since a person having ordinary skill in the art can appreciate the implementation detail and the modification thereto of the present method invention through the disclosure of the device invention, repeated and redundant description is thus omitted. Note that the shape, size, and ratio of any element in the disclosed figures are exemplary for understanding, not for limiting the scope of this invention. Furthermore, there is no step sequence limitation for the method inventions as long as the execution of each step is applicable. In some instances, the steps can be performed simultaneously or partially simultaneously.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A time-interleaved analog-to-digital converter (TIADC) configured to convert an input signal to generate a digital output signal, comprising:
an analog-to-digital converter (ADC) group comprising a first asynchronous sub-ADC and a second asynchronous sub-ADC, wherein the first asynchronous sub-ADC and the second asynchronous sub-ADC convert the input signal at different time points to respectively generate a first digital output code and a second digital output code, and the first asynchronous sub-ADC and the second asynchronous sub-ADC respectively generate a first conversion completion signal and a second conversion completion signal upon completion of one analog-to-digital conversion operation;
a digital code calibration circuit coupled to the ADC group and configured to correct one of the first digital output code and the second digital output code to obtain the digital output signal; and
a sub-ADC calibration circuit coupled to the ADC group and the digital code calibration circuit and configured to generate a control signal according to the first conversion completion signal and the second conversion completion signal;
wherein at least one of the first asynchronous sub-ADC and the second asynchronous sub-ADC changes a conversion speed of an analog-to-digital conversion operation according to the control signal.

2. The TIADC of claim 1, wherein the sub-ADC calibration circuit comprises:
a logic circuit configured to generate an indication signal according to the first conversion completion signal and the second conversion completion signal; and
a flip-flop coupled to the logic circuit and configured to generate the control signal according to the indication signal.

3. The TIADC of claim 1, wherein the sub-ADC calibration circuit comprises:
a first logic circuit configured to generate an indication signal according to the first conversion completion signal and the second conversion completion signal;
a flip-flop coupled to the first logic circuit and configured to temporarily store the indication signal; and
a second logic circuit coupled to the flip-flop and configured to generate the control signal according to the control signal, the first conversion completion signal, and a third conversion completion signal;
wherein the first conversion completion signal and the third conversion completion signal are generated by the first asynchronous sub-ADC in two consecutive operating cycles.

4. The TIADC of claim 1, wherein the first asynchronous sub-ADC comprises a comparator, and the sub-ADC calibration circuit adjusts an operating current of the comparator through the control signal to change the conversion speed of the analog-to-digital conversion operation of the first asynchronous sub-ADC.

5. The TIADC of claim 1, wherein the first asynchronous sub-ADC comprises a comparator and a control circuit, the comparator generates a comparison completion signal upon completion of a comparison operation, the control circuit generates an asynchronous clock according to the comparison completion signal, and the control circuit delays the asynchronous clock according to the control signal to change the conversion speed of the analog-to-digital conversion operation of the first asynchronous sub-ADC.

6. The TIADC of claim 1, wherein the ADC group further comprises a third asynchronous sub-ADC and a fourth asynchronous sub-ADC; the first asynchronous sub-ADC, the second asynchronous sub-ADC, the third asynchronous sub-ADC, and the fourth asynchronous sub-ADC operate sequentially.

7. The TIADC of claim 1, wherein the first asynchronous sub-ADC performs a first analog-to-digital conversion operation, the second asynchronous sub-ADC performs a second analog-to-digital conversion operation, and a third analog-to-digital conversion operation exists between the first analog-to-digital conversion operation and the second analog-to-digital conversion operation.

8. The TIADC of claim 1, wherein the first asynchronous sub-ADC operates in a first cycle and a second cycle that are continuous in time; the ADC group further comprises a third asynchronous sub-ADC and a fourth asynchronous sub-ADC; the third asynchronous sub-ADC and the fourth asynchronous sub-ADC respectively generate a third conversion completion signal and a fourth conversion completion signal; the sub-ADC calibration circuit generates the control signal in the first cycle according to the first conversion completion signal and the second conversion completion signal, and generates the control signal in the second cycle according to the third conversion completion signal and the fourth conversion completion signal.

9. A method for calibrating a time-interleaved analog-to-digital converter (TIADC) that comprises a first asynchronous sub-ADC and a second asynchronous sub-ADC, wherein the first asynchronous sub-ADC and the second asynchronous sub-ADC convert an input signal at different time points to respectively generate a first digital output code and a second digital output code, and the first asynchronous sub-ADC and the second asynchronous sub-ADC respectively generate a first conversion completion signal and a second conversion completion signal upon completion of one analog-to-digital conversion operation, the method comprising:
generating a control signal according to the first conversion completion signal and the second conversion completion signal; and
changing a conversion speed of an analog-to-digital conversion operation of at least one of the first asynchronous sub-ADC and the second asynchronous sub-ADC according to the control signal.

10. The method of claim 9 further comprising:
generating an indication signal according to the first conversion completion signal and the second conversion completion signal; and
generating the control signal according to the indication signal.

11. The method of claim 9 further comprising:
generating an indication signal according to the first conversion completion signal and the second conversion completion signal;
temporarily storing the indication signal; and
generating the control signal according to the control signal, the first conversion completion signal, and a third conversion completion signal;
wherein the first conversion completion signal and the third conversion completion signal are generated by the first asynchronous sub-ADC in two consecutive operating cycles.

12. The method of claim 9, wherein the first asynchronous sub-ADC comprises a comparator, and the method further comprises:
adjusting an operating current of the comparator through the control signal to change the conversion speed of the analog-to-digital conversion operation of the first asynchronous sub-ADC.

13. The method of claim 9, wherein the first asynchronous sub-ADC comprises a comparator and a control circuit, the comparator generates a comparison completion signal upon completion of a comparison operation, and the control circuit generates an asynchronous clock according to the comparison completion signal, the method further comprising:
delaying the asynchronous clock according to the control signal to change the conversion speed of the analog-to-digital conversion operation of the first asynchronous sub-ADC.

14. The method of claim 9, wherein the TIADC further comprises a third asynchronous sub-ADC and a fourth asynchronous sub-ADC; the first asynchronous sub-ADC, the second asynchronous sub-ADC, the third asynchronous sub-ADC, and the fourth asynchronous sub-ADC operate sequentially.

15. The method of claim 9, wherein the TIADC further comprises a third asynchronous sub-ADC and a fourth asynchronous sub-ADC; the first asynchronous sub-ADC, the third asynchronous sub-ADC, the second asynchronous sub-ADC, and the fourth asynchronous sub-ADC operate sequentially.

16. The method of claim 9, wherein the first asynchronous sub-ADC operates in a first cycle and a second cycle that are continuous in time; the TIADC further comprises a third asynchronous sub-ADC and a fourth asynchronous sub-ADC; the third asynchronous sub-ADC and the fourth asynchronous sub-ADC respectively generate a third conversion completion signal and a fourth conversion completion signal; the method generates the control signal in the first cycle according to the first conversion completion signal and the second conversion completion signal, and generates the control signal in the second cycle according to the third conversion completion signal and the fourth conversion completion signal.
